(19) United States
(12) Patent Application Publication
(10) Pub. No.: US 2026/0007079 A1
(43) Pub. Date: Jan. 1, 2026

(54) SELECTIVE ETCHING OF TOP ELECTRODE METAL TO PHASE-CHANGE MATERIAL BY TUNING WAFER TEMPERATURE

(71) Applicants: International Business Machines Corporation, Armonk, NY (US); TOKYO ELECTRON LIMITED, Minato-ku, Tokyo (JP)

(72) Inventors: Luxherta Buzi, Chappaqua, NY (US); Devi Koty, Fishkill, NY (US); Qingyun Yang, Hope Junction, NY (US); Robert L. Bruce, White Plains, NY (US)

(21) Appl. No.: 18/756,708

(22) Filed: Jun. 27, 2024

(51) Int. Cl. H10N 70/00; H10B 63/10

(52) U.S. Cl. CPC H10N 70/063; H10B 63/10; H10N 70/8828

(57) ABSTRACT

Provide an initial structure including a bottom electrode layer, a phase change material layer outward of the bottom electrode, a top electrode layer outward of the phase change material layer, and a patterned hard mask outward of the phase change material layer. Etch the initial structure using a first halogen plasma etchant at high wafer temperature to partially remove portions of the top electrode layer not protected by the patterned hard mask to produce an intermediate structure. Etch the intermediate structure using a second halogen plasma etchant at low wafer temperature to remove a remaining portion of the top electrode layer down to the phase change material layer, leaving a web of top electrode layer material under the patterned hard mask. Etch portions of the phase change material layer not protected by the web of top electrode layer material down to the bottom electrode layer, and remove the patterned mask.

### BACKGROUND

The present invention relates generally to semiconductor devices, and more specifically, to semiconductor fabrication techniques and resultant structures, such as for phase-change memory and the like.

Continued progress in computing has led to a search for larger, faster memories, for applications such as hybrid cloud computing and the like. One such memory is three-dimensional crosspoint non-volatile memory (NVM). Phase-change memory is a type of non-volatile random-access memory that employs a phase-change material (PCM) such as chalcogenide glass or the like. Heat produced by an electric heating element is used to transition the PCM between amorphous and crystalline states and in some instances to achieve intermediary states, thereby providing multi-bit cells.

### BRIEF SUMMARY

Principles of the invention provide techniques for selective etching of top electrode metal to PCM by tuning wafer temperature. In one aspect, an exemplary method includes providing an initial structure including a bottom electrode layer, a phase change material layer outward of the bottom electrode, a top electrode layer outward of the phase change material layer, and a patterned hard mask outward of the phase change material layer; etching the initial structure using a first halogen plasma etchant at high wafer temperature to partially remove portions of the top electrode layer not protected by the patterned hard mask to produce an intermediate structure; etching the intermediate structure using a second halogen plasma etchant at low wafer temperature to remove a remaining portion of the top electrode layer down to the phase change material layer, leaving a web of top electrode layer material under the patterned hard mask; etching portions of the phase change material layer not protected by the web of top electrode layer material down to the bottom electrode layer; and removing the patterned hard mask.

In another aspect, an exemplary phase change memory array includes a plurality of bit lines; a plurality of word lines intersecting the plurality of bit lines at a plurality of grid points; and a plurality of phase change memory (PCM) cells located at the plurality of grid points. Each phase change memory (PCM) cell of the plurality of phase change memory (PCM) cells is electrically connected to a corresponding bit line and selectively grounded under control of a corresponding one of the word lines, and each phase change memory (PCM) cell includes a top electrode, a phase change material, a bottom electrode, and a side layer located on sides of the top electrode and the phase change material, the side layer including elements from the phase change material and halogen plasma etchant residue.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, a remote processor, a pump, a valve, or the like by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-7 show successive steps in a fabrication process, in accordance with aspects of the invention;

FIG. 8 shows recrystallization fraction versus time for a reference sample and for PCM etched by halogen plasma at different temperatures;

FIG. 9 shows test chamber in accordance with aspects of the invention;

FIG. 10 shows a phase-change memory (PCM) cell fabricated in accordance with aspects of the invention; and

FIG. 11 shows an array of phase-change memory (PCM) cells fabricated in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), in aspects of the invention an exemplary method includes, as seen in FIG. 3, providing an initial structure including a bottom electrode layer 1001, a phase change material layer 1003 outward of the bottom electrode, a top electrode layer 1005 outward of the phase change material layer, and a patterned hard mask 1007A outward of the phase change material layer; and as seen in FIG. 4, etching the initial structure using a first halogen plasma etchant at high wafer temperature to partially remove portions of the top electrode layer 1005 not protected by the patterned hard mask 1007A to produce an intermediate structure. Note that the wafer temperature refers to the bulk temperature of the materials in the stack. Further steps include, as seen in FIG. 5, etching the intermediate structure using a second halogen plasma etchant at low wafer temperature to remove a remaining portion of the top electrode layer 1005 down to the phase change material layer 1003, leaving a web of top electrode layer material 1005C under the patterned hard mask 1007A; as seen in FIG. 6, etching portions of the phase change material layer 1003 not protected by the web of top electrode layer material 1005C down to the bottom electrode layer 1001; and, as seen in FIG. 7, removing the patterned hard mask 1007A.

Reference to a “first” halogen plasma etchant and a “second” halogen plasma etchant is for convenience and simply respectively means the etchants used at the high and low wafer temperatures. Generally, the first and second etchants can be the same or different, and the high and low temperature etching can be in the same or different chambers. In a non-limiting example, the first and second etchants are identical and the same chamber is used to etch at both the high and low temperatures (etching of the portions of the phase change material can also be done with this same etchant in one or more embodiments). For example, the etching of the initial structure, the etching of the intermediate structure, and the etching of the portions of the phase change material are all carried out in a vacuum chamber 2007 while maintaining vacuum.

In a non-limiting example, the temperature of the wafer is measured with a temperature probe 2005 such as a thermocouple, thermistor, or the like.

One or more embodiments further include cooling the intermediate structure to the low temperature, prior to etching the intermediate structure using the identical halogen plasma etchant at the low temperature. The cooling can include, for example, exposure to liquid nitrogen.

The high temperature can be, for example, at least 40° C., at least 65° C., at least 80° C., or at least 100° C.

The high temperature can be, for example, less than 0° C., less than −10° C., or less than-20° C.

In some instances, the low temperature is between −10° C. and −20° C. and the high temperature is between 40° C. and 200° C. or even 250° C.

In one or more embodiments, in the providing step, the phase change material layer includes GST. Note that the GST can be doped or undoped, and is a non-limiting example; other embodiments could use other PCM.

Note that the top and bottom electrodes can be formed, for example, of metals. In some cases, the electrodes can be formed from materials selected from the group consisting of TiN, TaN, Ta, Ti, and K.

In some cases, the etching of the initial structure using the first halogen plasma etchant at high wafer temperature to partially remove portions of the top electrode layer not protected by the patterned hard mask is carried out so as to leave a remaining thickness of the top electrode layer sufficient to be thicker than a diffusion depth of the first halogen plasma etchant into the top electrode layer. This remaining thickness of the top electrode layer can range, for example, from 10 nm-20 nm.

In some cases, the etching steps are carried out at a pressure of about 4-100 mTorr.

In another aspect, an exemplary phase change memory (PCM) array includes a plurality of bit lines 1310; a plurality of word lines 1306 intersecting the plurality of bit lines at a plurality of grid points; and a plurality of phase change memory (PCM) cells located at the plurality of grid points. Each phase change memory (PCM) cell of the plurality of phase change memory (PCM) cells is electrically connected to a corresponding bit line 1310 and selectively grounded under control of a corresponding one of the word lines 1306. Each phase change memory (PCM) cell includes a top electrode 809, a phase change material 811/807 (e.g., GST (germanium-antimony-tellurium or Ge2Sb2Te5)), a bottom electrode 803, and a side layer located on sides of the top electrode and the phase change material. The side layer 1015 includes elements from the phase change material and halogen plasma etchant residue. For example, in some cases, the side layer ranges in thickness from 1 nm-5 nm.

Techniques as disclosed herein can provide substantial beneficial technical effects. Some embodiments may not have these potential advantages and these potential advantages are not necessarily required of all embodiments. By way of example only and without limitation, in addition to those discussed above, one or more embodiments may provide one or more of providing ability to achieve larger, faster memories, for applications such as hybrid cloud computing and the like, such as a three-dimensional crosspoint non-volatile memory (NVM) or the like, using a PCM where an improved etching process reduces or eliminates damage to the PCM during etching, thereby achieving a desirable switching time for the PCM (i.e., shorter switching time as compared to GST (GeSbTe/germanium-antimony-tellurium) in cells produced using prior-art etching).

As noted above, continued progress in computing has led to a search for larger, faster memories, for applications such as hybrid cloud computing and the like. One such memory is three-dimensional crosspoint non-volatile memory (NVM). One or more embodiments advantageously provide a process to enable top electrode (TE) metal etching with halogen chemistry, by lowering the temperature to increase the etch selectivity to PCM and stop the etching on the PCM without damage. Advantageously, in one or more embodiments, the same chemistry can be used to etch a remaining bottom portion of PCM by decreasing the etching temperature. Thus, one or more embodiments carry out an initial partial etch of the TE at high temperature and then lower the temperature to etch the remaining portion of TE metal, to mitigate PCM damage. In one or more embodiments, a good etch stop on the PCM allows additional plasma exposure to trim the TE (e.g., TiN). In one or more embodiments, the low temperature limits the diffusion rate of halogens into the bulk material.

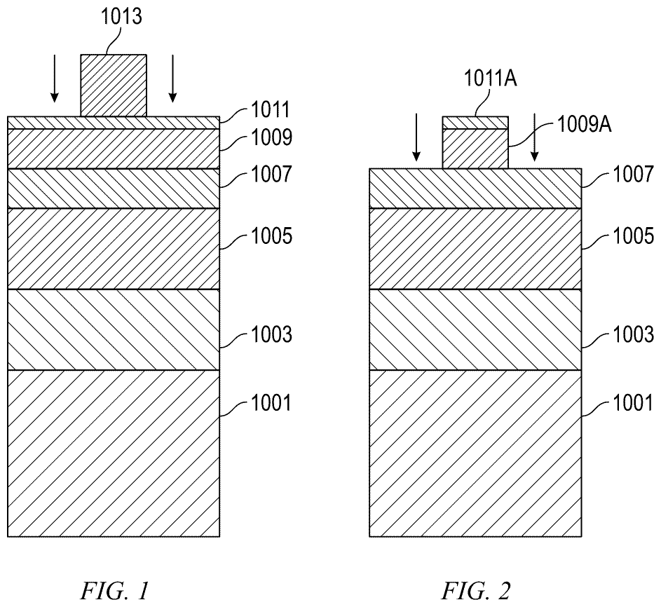

One or more embodiments can be applied on a patterned substrate where both the TE and PCM need to be etched. Referring now to the starting structure of FIG. 1, a typical stack can include a bottom electrode (BE) layer 1001, a PCM layer 1003 (e.g., GST), a TE layer 1005 (e.g., TiN), a hard mask 1007 (e.g., SiO and/or SiN), an organic planarization layer (OPL) 1009, an ARC (anti-reflective coating) 1011 (e.g., SiARC), and photo resist (PR) 1013 that has been patterned. Such a structure can be produced using known deposition and lithographic techniques. FIG. 2 shows the structure of FIG. 1 after etching the OPL 1009 and ARC 1011. The OPL and ARC protected from the etching using the patterned PR 1013 are designated as 1009A, 1011A. FIG. 3 shows the structure of FIG. 2 after the hard mask 1007 has been patterned based on layers 1009A, 1011A. The patterned hard mask is designated as 1007A. The vertical arrows represent high-temperature halogen plasma etching of the TE 1005.

Referring to FIG. 4, once the TE has been etched down to a thin layer 1005A and a reduced cross-section web 1005B, decrease the temperature to etch the rest of the TE and the PCM 1003, using the same halogen chemistry. Note that the patterned hard mask has been further thinned and is now designated as 1007B. The result is shown in FIG. 5 where the remaining TE is designated as 1005C. Note that the patterned hard mask has been still further thinned and is now designated as 1007C. FIG. 6 shows etching of the PCM using the low temperature halogen plasma. Note that the patterned hard mask has been yet further thinned and is now designated as 1007D. FIG. 7 shows the result of the etching of FIG. 6 after removal of the patterned hard mask 1007A. The etched PCM is designated as 1003A. At 1015, note that cryogenic etching includes redeposition and/or co-deposition of the PCM on the top electrode, with halogen species from the plasma. Thus, there is a side layer 1015 on the remaining TE 1005C and etched PCM 1003A that includes elements from the PCM and also from the halogen(s) used for etching; TE material and/or other residue from the plasma may also be present in the co-mixture. In some instances, the thickness of the side layer 1015 ranges up to 5 nm (e.g., from 1 to 5 nm in some cases).

One or more embodiments thus include tuning the temperature when etching each layer, using the same plasma conditions. Indeed, one or more embodiments use etch temperature/wafer temperature as an additional “knob” to control etching, and reduce or eliminate damage of the PCM 1003 in the depicted stack. In one or more embodiments, the PCM includes GST and/or its derivatives; they are typically very sensitive to the etch chemistry, especially if a halogen is used. The top electrode 1005 can be a metal and/or metallic compound such as TiN, TaN, Ta, W, WN, or the like. Heretofore, in prior art techniques, when etching metal and then landing on the PCM, the PCM has been exposed to harsh chemistry (at high temperature) which causes damage.

In one or more embodiments, during the etching process, the temperature is tuned in such a way that a higher temperature is used to etch through most of the (e.g., metal) top electrode, as seen in FIG. 4. The higher temperature advantageously allows for straight sidewalls and a faster etch, as compared to a lower temperature. However, one or more embodiments do not etch all the way through the top electrode at high temperature, but rather leave part of the TE 1005A so that the PCM 1003 is covered. Then, the temperature is switched from high to low and the rest of the metal is etched at low temperature. In one or more embodiments, this advantageously ensures full removal of the metal with little or no damage to the PCM.

We have found in experiments that in electrically testing cells produced in accordance with aspects of the invention, halogen residue is found on the sidewall as shown at 1015 (in co-mixture with other materials as discussed above) but the GST PCM still has a good switching speed. In cross-sectioning samples and looking at the elemental composition, we have noted sidewall co-deposited product typical for cryogenic etching.

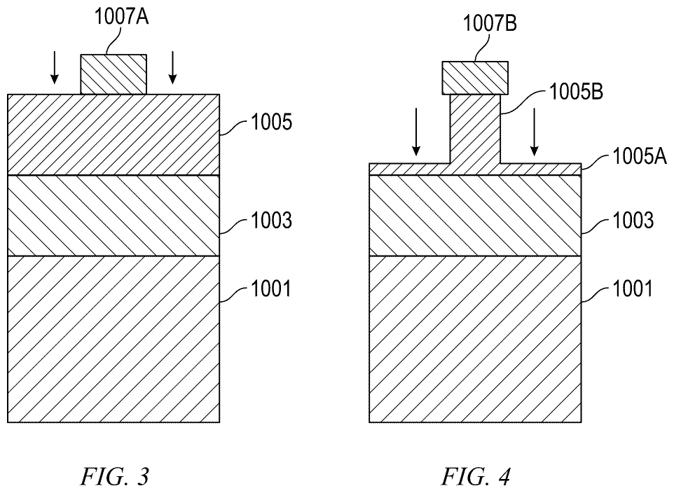

FIG. 8 shows exemplary measurements on blanket (not patterned) undoped GST (Ge₂Sb₂Te₅ (GST-225)) films at high and low temperatures. It is anticipated that similar good results could be obtained with doped GST in terms of switching speed and that similar beneficial effects would be obtained with other PCMs. We have found that switching to low temperature preserves the GST. In FIG. 8, the “Reference” film was not exposed to any plasma. The other films were exposed to plasma and etched, and were tested with a laser to input a known amount of heat to the film. The recrystallization properties were tested. A pertinent property of the GST film is the switching speed (time to switch between two phases, amorphous and crystalline). Generally, a better film has a shorter switching time. The reference layer has a switching time of about 20 ns (time point where a recrystallization faction of 1.0 is achieved). On the other hand, the high temperature (80° C.) etch takes 70-80 ns or more to re-crystallize. The low temperature (−20° C.) etch takes only about 20-30 ns to re-crystallize, which is much better than the high temperature value. In the particular example of FIG. 8, the 0° C., etch has a recrystallization time closer to the high temperature value. The X-axis is time in nanoseconds (ns) on a log scale.

The phase change material layer may be formed, for example, from a mixture of Gallium (Ga) and Antimony (Sb) and at least one of Tellurium (Te), Silicon (Si), Germanium (Ge), Arsenic (As), Selenium (Se), Indium (In), Tin (Sn), Bismuth (Bi), Silver (Ag), Gold (Au), and additional Antimony (Sb). Generally, processes can be performed in any type of reactive ion etching (RIE) chamber (Inductively Coupled Plasma Etching (ICP RIE), Capacitively Coupled Plasma Etching (CCP), electron cyclotron resonance electron cyclotron resonance (ECR) plasma etching, etc.) at a temperature in the range-20-200° C. at a range of about 4-100 millitorr (mTorr) for a time in a range of about 5-400 seconds(s), using inert or non-reactive carrier gas (e.g., Ar, Ne, He, Xe, N), halogens and C—H gas for passivation. The skilled artisan can readily determine empirically, given the teachings herein, the etch time at each temperature.

Thus, the PCM has a reset speed higher (near the Reference as-deposited value) when etched at low temperature in a halogen chemistry. One or more embodiments accordingly lower the temperature of the wafer when using halogen plasma, as discussed further below.

In one or more embodiments, the high and low temperature halogen etching are carried out in the same chamber as part of a continuous process. In one or more embodiments, the break between the high temperature and low temperature processes is achieved by maintaining the wafer under vacuum, lowering the temperature, and resuming the etching plasma. It will take some time for the wafer to cool down; the skilled person will be able to predict the cooldown time, if needed, using known thermal analysis techniques such as finite element analysis and/or finite difference analysis, or using analytical techniques/closed form solutions in the case of simple geometries. Alternatively or additionally, cooldown time can be determined/verified empirically with measurements. Advantageously, one or more embodiments use a single chemistry; there is no need to change the chemistry to reduce the amount of halogens.

In one or more embodiments, it is possible to limit the amount of hydrocarbons in the plasma which would normally be used for sidewall passivation.

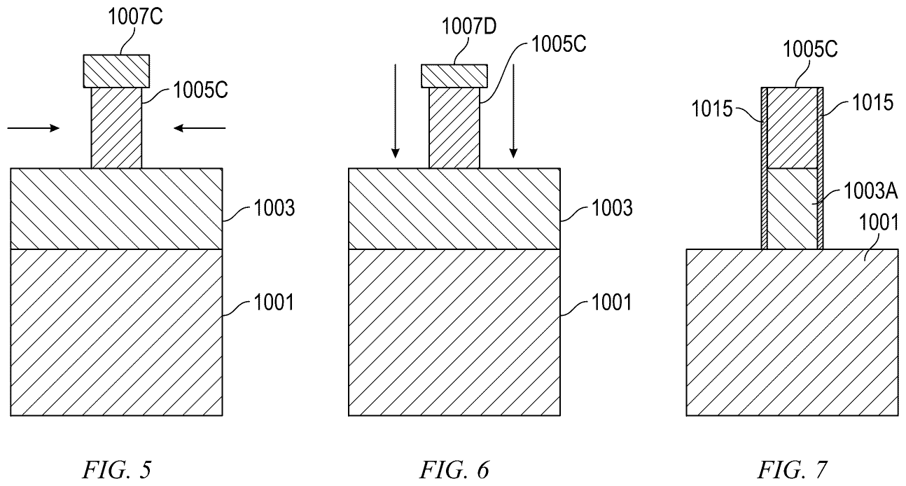

In one or more embodiments, cooling is carried out using liquid nitrogen (LN₂). Referring to FIG. 9, for example, run the LN₂ from the source 2011 through a duct to a stage 2001 in the chamber 2007 that the wafer 2003 is mounted on. In one or more embodiments, a high temperature can be at least 40° C., or at least 65° C., or at least 80° C., or even at least 100° C. In one or more embodiments, a low temperature can be less than 0° C. down to −20° C., less than −10° C. down to −20° C., or even less than −20° C. The temperature of the wafer/substrate can be measured with a temperature probe 2005 such as a thermocouple, thermistor, or the like. Note the plasma supply 2013 and vacuum pump 2009. One or more embodiments further include a controller 2099 coupled to the thermocouple 2005 that causes the setup to carry out the process. For example, controller 2099 controls the plasma supply 2013 and the temperature (e.g., by a valve controlling the LN₂ flow) to carry out the method. In one or more embodiments, the thermocouple is located at the interface between the 2001 stage and wafer 2003. Note the lead, not separately numbered, from the thermocouple 2005 to the controller 2099 and coupled to the pump 2009, plasma supply 2013, and LN₂ source 2011 to control the flow of LN₂ to adjust the temperature as well as to control the plasma and the vacuum pump. Controller 2099 can convert the signal from element 2005 into a digital value of temperature, for example. Given the teachings herein, the skilled artisan can implement the controller in software or firmware running on a processor, on digital circuitry, or the like.

Further considering a digital circuitry implementation of the controller, to implement digital circuitry to carry out control techniques described herein, computer-aided semiconductor integrated circuit (IC) logic design, simulation, test, layout, and/or manufacture can be employed. The computerized design process can represent functional and/or structural design features in a design structure generated using electronic computer-aided design (ECAD). A suitable hardware-description language (HDL) can be employed. The skilled artisan can synthesize digital logic circuits to carry out desired control and other functionality, using known computer-aided design techniques. The controller 2099 carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture. Such a known design flow for synthesizing digital circuitry includes processes, machines and/or mechanisms for processing design structures or devices to generate logically or otherwise functionally equivalent representations of design structures and/or devices. The design structures processed can be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array). Design structures can be generated using ECAD. Use can be made of HDL design entities or other data structures conforming to and/or compatible with lower-level HDL design languages such as Verilog and VHDL, and/or higher level design languages such as C or C++.

It is worth noting that at cryogenic temperatures, the etch rate starts to drop, so optionally, it is possible to be a little more aggressive on the etchant chemistry without impacting the GST properties.

Implementation of 3D cross-point technology requires a complex and thick stack of materials, and features need to be scaled to a small critical dimension (CD). One or more embodiments facilitate continued progress in computing by providing larger, faster memories, for applications such as hybrid cloud computing and the like, using three-dimensional crosspoint non-volatile memory (NVM).

It is worth noting that downward etching of the SiARC can be carried out, for example, using an etchant such as CHF₃/CF₄, followed by downward etching of the OPL using an etchant such as Ar/N₂/CH₄/O₂. For example, reactive ion etching (RIE) can be utilized for these operations in one or more embodiments. Generally, downward etching is suggested in the figures by downward arrows.

In the plasma etching process, there will typically be a carrier gas with a higher flow rate than the other constituents. Various known plasma etching chambers can be used, as will be apparent to the skilled artisan, given the teachings herein. As discussed above, again, generally, processes can be performed in any type of RIE chamber (Inductively Coupled Plasma Etching (ICP RIE), Capacitively Coupled Plasma Etching (CCP), electron cyclotron resonance (ECR) plasma etching, etc.) at a temperature in the range −20-200° C. at a range of about 4-100 millitorr (mTorr) for a time in a range of about 5-400 seconds(s), using inert or non-reactive carrier gas (e.g., Ar, Ne, He, Xe, N), halogens and C—H gas for passivation.

Given the teachings herein, the skilled artisan will appreciate that techniques according to aspects of the invention can be used to fabricate a variety of structures, such as, for example, arrays of memory devices, such as phase change memory.

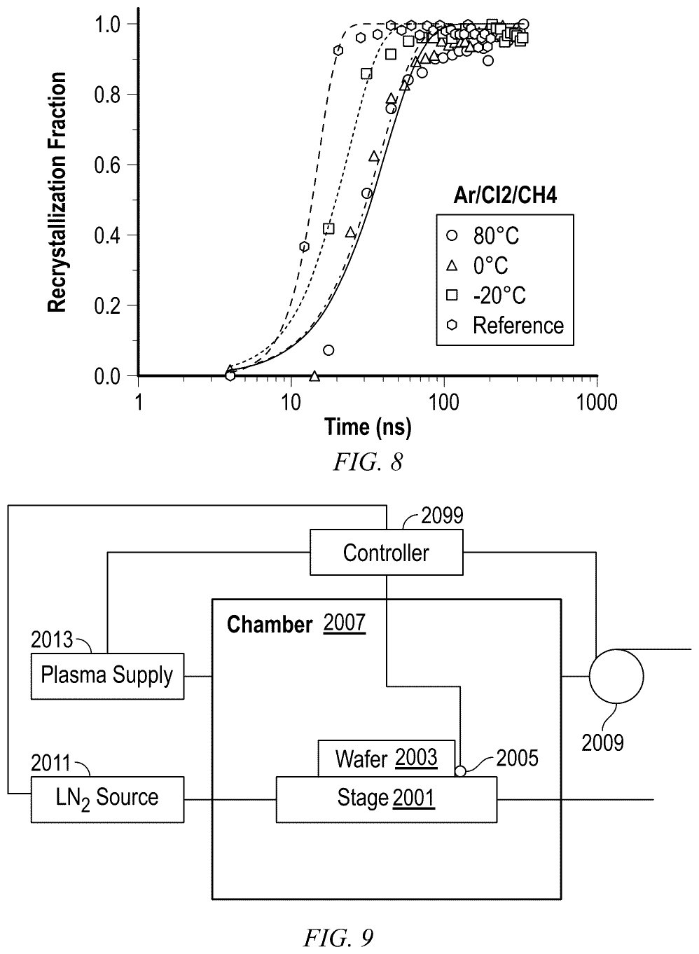

FIG. 10 shows a PCM cell formed using aspects of the invention. In one or more embodiments, the PCM cell includes a top electrode 809, a phase change material 811/807 (e.g., GST (germanium-antimony-tellurium or Ge₂Sb₂Te₅)), and a bottom electrode 803. The phase change material 811/807 can include a first portion 811 and/or a second portion 807 depending on its state. It should be understood that GST is useful as a medium of storage or memory given its ability to affect a reversible phase change when heated and cooled rapidly, or heated slowly, switching between an amorphous state and a crystalline state. According to one or more embodiments, the first portion of GST 811 is an amorphous state GST and the second portion of GST 807 is a crystalline state GST. The portion 811 may be electrically programmed to a crystalline state GST. It should be understood that portions 811/807 are the same material, and that the presence of portion 811 depends on the state of the device (i.e., if the GST is amorphized into RESET (high resistance), then portion 811 is present). The PCM cell is disposed in dielectric layer 801 (e.g., silicon). Given the teachings herein, the skilled artisan can form cells such as that depicted in FIG. 10 based on the process steps illustrated in FIGS. 1-7.

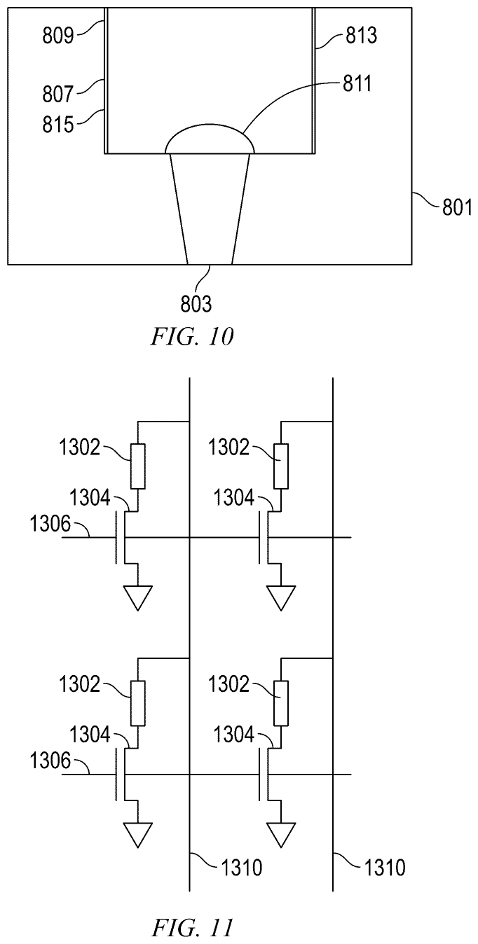

FIG. 11 shows a PCM array with a plurality of bit lines 1310 and a plurality of word lines 1306 that intersect the plurality of bit lines at a plurality of cell locations. A plurality of PCM cells 1302, such as that of FIG. 10, are located at each of the plurality of cell locations and connected through the electrodes. Each of the cells 1302 is electrically connected to a corresponding bit line 1310 and selectively grounded under control of a corresponding one of the word lines 1306 (e.g., a respective transistor 1304 is a field effect transistor turned off or on by a signal from word line 1306 applied to its gate, in a known manner).

Following the structure depicted FIG. 7, to obtain the array of FIG. 11 of cells such as in FIG. 10, etch/pattern the bottom electrode, encapsulate with dielectric, polish the top, and form back end of line (BEOL) wiring to connect the cells into the array.

As will be appreciated by the skilled artisan, appropriate peripheral circuitry (not shown) and a suitable controller (not shown), can be provided. Given the teachings herein, the skilled artisan will be able to provide any additional desired/required peripheral circuitry, voltage supply, elements to interface with peripheral circuitry, and a controller by adapting known techniques. The discussion of implementing controller 2099 in digital circuitry is also generally applicable to implementing an array controller in digital circuitry.

The voltage supply can be controlled by the controller to supply appropriate voltages/programming pulses, and can be part of the controller or a separate unit. These elements are cooperatively configured for input/output and so on. Given the teachings herein, the skilled artisan will be able to provide any additional desired/required peripheral circuitry, voltage/power supply, elements to interface with peripheral circuitry, and the controller by adapting known techniques. To implement digital circuitry for a controller or the like, computer-aided semiconductor integrated circuit (IC) logic design, simulation, test, layout, and/or manufacture can be employed. The computerized design process can represent functional and/or structural design features in a design structure generated using electronic computer-aided design (ECAD). A suitable hardware-description language (HDL) can be employed. The skilled artisan can synthesize digital logic circuits to carry out desired control and other functionality, using known computer-aided design techniques. Refer to the discussion of implementing controller 2099 in digital circuitry

In one or more embodiments, the peripheral circuitry, the power supply, and the controller are cooperatively configured to store and read values.

It is worth noting that the cell of FIG. 10 and the array of FIG. 11 are shown at a high level of generality, and that conventional aspects of semiconductor fabrication will now be described at a high level of generality, it being understood that a pertinent aspect is the fabrication of the cells using selective etching of the top electrode metal to phase-change material by tuning the temperature as described herein and that other aspects can be implemented by adapting conventional techniques. Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system; for example, where larger, faster memories are desired for applications such as hybrid cloud computing and the like (e.g., PCM, three-dimensional crosspoint NVM). Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A method comprising:
providing an initial structure comprising a bottom electrode layer, a phase change material layer outward of the bottom electrode, a top electrode layer outward of the phase change material layer, and a patterned hard mask outward of the phase change material layer;
etching the initial structure using a first halogen plasma etchant at high wafer temperature to partially remove portions of the top electrode layer not protected by the patterned hard mask to produce an intermediate structure;
etching the intermediate structure using a second halogen plasma etchant at low wafer temperature to remove a remaining portion of the top electrode layer down to the phase change material layer, leaving a web of top electrode layer material under the patterned hard mask;
etching portions of the phase change material layer not protected by the web of top electrode layer material down to the bottom electrode layer; and
removing the patterned hard mask.

2. The method of claim 1, wherein the first and second halogen plasma etchants are identical.

3. The method of claim 2, wherein the etching of the portions of the phase change material layer includes etching with the identical halogen plasma etchant.

4. The method of claim 3, wherein the etching of the initial structure, the etching of the intermediate structure, and the etching of the portions of the phase change material are all carried out in a vacuum chamber while maintaining vacuum.

5. The method of claim 4, further comprising cooling the intermediate structure to the low temperature prior to etching the intermediate structure using the identical halogen plasma etchant at the low temperature.

6. The method of claim 5, wherein the cooling comprises exposure to liquid nitrogen.

7. The method of claim 5, wherein the high temperature is at least 40° C.

8. The method of claim 7, wherein the high temperature is at least 65° C.

9. The method of claim 8, wherein the high temperature is at least 80° C.

10. The method of claim 9, wherein the high temperature is at least 100° C.

11. The method of claim 5, wherein the low temperature is less than 0° C.

12. The method of claim 11, wherein the low temperature is less than −10° C.

13. The method of claim 12, wherein the low temperature is less than −20° C.

14. The method of claim 5, wherein the low temperature is between −10° C. and −20° C. and the high temperature is between 40° C. and 250° C.

15. The method of claim 1, wherein, in the providing step, the phase change material layer comprises GST.

16. The method of claim 1, wherein the etching of the initial structure using the first halogen plasma etchant at high wafer temperature to partially remove portions of the top electrode layer not protected by the patterned hard mask is carried out so as to leave a remaining thickness of the top electrode layer sufficient to be thicker than a diffusion depth of the first halogen plasma etchant into the top electrode layer.

17. The method of claim 16, wherein the remaining thickness of the top electrode layer ranges from 10 nm-20 nm.

18. The method of claim 1, wherein the etching steps are carried out at a pressure of about 4-100 mTorr.

19. A phase change memory (PCM) array comprising:
a plurality of bit lines;
a plurality of word lines intersecting the plurality of bit lines at a plurality of grid points; and
a plurality of phase change memory (PCM) cells located at the plurality of grid points;
wherein:
each phase change memory (PCM) cell of the plurality of phase change memory (PCM) cells is electrically connected to a corresponding bit line and selectively grounded under control of a corresponding one of the word lines; and
each phase change memory (PCM) cell includes a top electrode, a phase change material (e.g., GST (germanium-antimony-tellurium or Ge2Sb2Te5)), a bottom electrode, and a side layer located on sides of the top electrode and the phase change material, the side layer including elements from the phase change material and halogen plasma etchant residue.

20. The phase change memory (PCM) array of claim 19, wherein the side layer ranges in thickness from 1 nm-5 nm.
